(19) United States
(12) Patent Application Publication
(10) Pub. No.: US 2025/0126820 A1
(43) Pub. Date: Apr. 17, 2025

(54) SEMICONDUCTOR DEVICE WITH NON-CONFORMAL WORK FUNCTION LAYERS AND METHODS OF FABRICATION THEREOF

(71) Applicant: TAIWAN SEMICONDUCTOR MANUFACTURING COMPANY, LTD., Hsinchu (TW)

(72) Inventors: Yi-Hong WANG, Taichung (TW); Hui-Hsuan KUNG, Taichung (TW); Yi-Lii HUANG, Hsinchu (TW); Ying-Ru LIN, Taichung (TW)

(21) Appl. No.: 18/487,451

(22) Filed: Oct. 16, 2023

(51) Int. Cl. H01L 29/66; H01L 29/08; H01L 29/78

(52) U.S. Cl. CPC H10D 30/024; H10D 30/6211; H10D 62/151; H10D 64/017

(57) ABSTRACT

Embodiments of the present disclosure provide a FinFET transistor having a gate structure including one or more non-conformal work function metal layers. In some embodiments, work function metal layers may be non-conformal in at least one of thickness, composition, and/or phases. The non-conformality in the work function metal layer lowers leakage, improve device performance, and increase device reliability.

### BACKGROUND

With the increasing down scaling of semiconductor devices, various processing techniques are adapted to allow for the manufacture of devices with increasingly smaller dimensions. As semiconductor devices continue to shrink, new challenges may occur in existing process technologies and existing device structures. For example, in fabrication of fin field effect transistors (FinFETs), conformal films are deposited as gate dielectric layers and gate electrode layers. However, as device dimension shrink, the conformally formed films may lead to gate leakage or other defects because top portions of the conformal film may become thinner or incur damages during processing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of an exemplary method for forming a semiconductor device according to embodiments of the present disclosure.

FIGS. 2-6, 6A-6B, 7A-7B, 8A-8B, 9A-9B, 10A-10D, 11A-11C, 12, and 12A-12B are schematic views of a semiconductor device at various stages of manufacturing a semiconductor device according to embodiments of the present disclosure.

FIGS. 13A-13E are schematic sectional views of work function metal film stacks according to embodiments of the present disclosure.

FIGS. 14A-14H are transmission electron microscopy (TEM) images and graphs of semiconductor devices fabricated according to embodiments of the present disclosure.

FIG. 15 is a flow chart of an exemplary method for forming a semiconductor device according to embodiments of the present disclosure.

FIGS. 16A-16B and 17A-17B are schematic views of a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of FinFETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region refers to a source and/or a drain. A source and a drain are interchangeably used.

Embodiments of the present disclosure provide a FinFET transistor having a gate structure including one or more non-conformal work function metal layers. In some embodiments, work function metal layers may be non-conformal in at least one of thickness, composition, and/or phases. In some embodiments, the non-conformal work function metal layer has a non-conformal thickness along a semiconductor fin in a FinFET transistor. For example, the overall thickness of work function metal layers is thicker along a top side of the semiconductor fin and thinner along sidewalls of the semiconductor fin. In some embodiments, the work function metal layers may be non-conformal in phase. For example, a first portion of the work function metal layer may be amorphous material and a second portion of the work function metal layer may be crystalline or polycrystalline material. In some embodiments, the work function metal layer may include an amorphous portion formed over the top surface of the semiconductor fin. The non-conformal in the work function metal layer may reduce leakage, reduce vertical resistance, improve device performance, and increase device reliability.

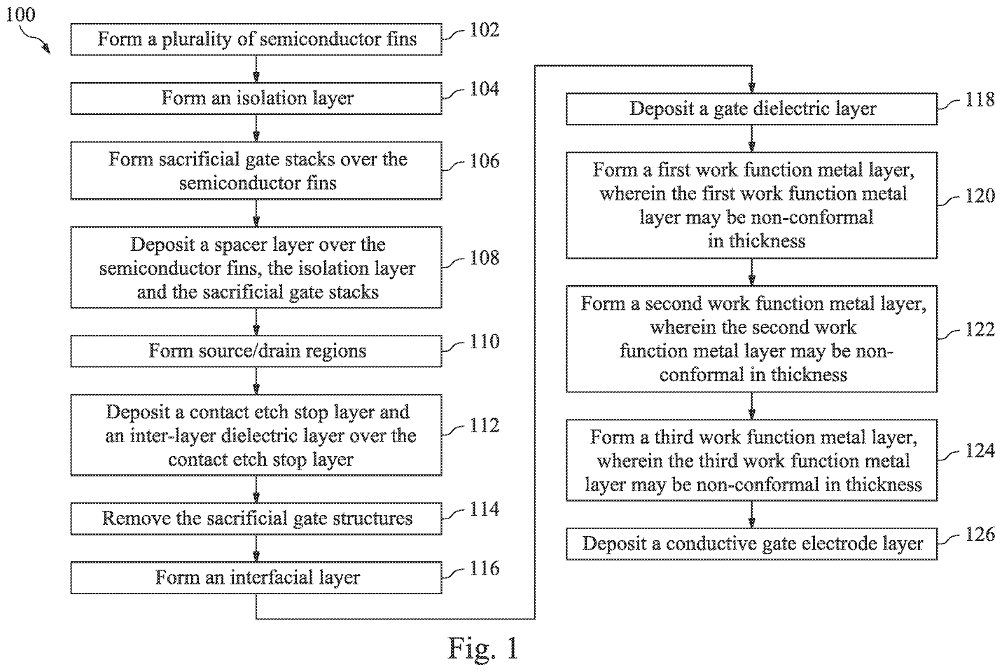

FIG. 1 is a flow chart of an exemplary method 100 for forming a semiconductor device according to embodiments of the present disclosure.

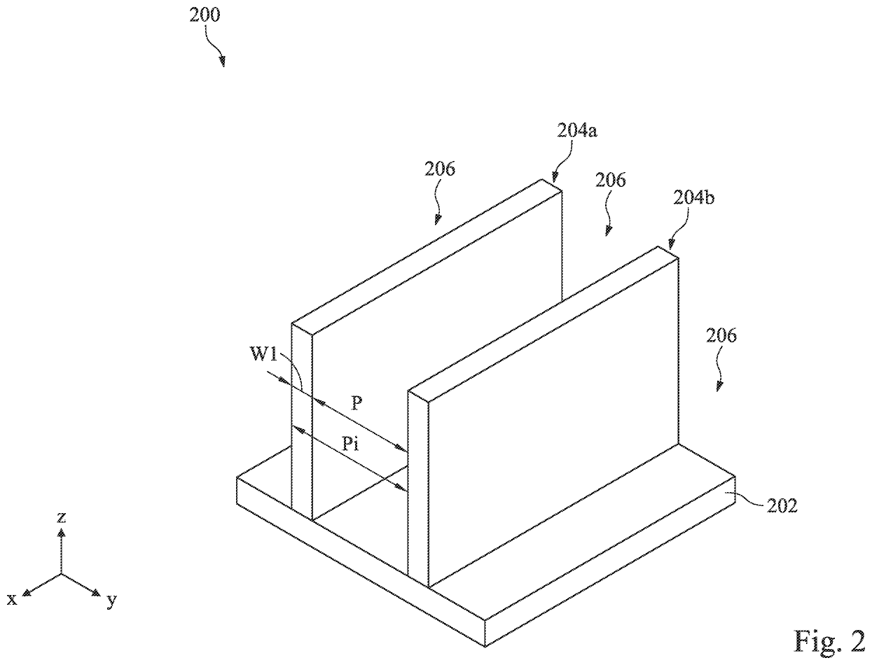

FIGS. 2-6, 6A-6B, 7A-7B, 8A-8B, 9A-9B, 10A-10D, 11A-11C, 12, and 12A-12B are schematic perspective views of a semiconductor device 200 at various stages of manufacturing the semiconductor device 200 according to embodiments of the present disclosure. In some embodiments, the semiconductor device 200 may be fabricated using the method 100.

At operation 102 of the method 100, fin structures 204a, 204b (collectively 204) are formed on a substrate 202, as shown in FIG. 2. FIG. 2 is a schematic perspective view of the semiconductor device 200 after operation 102. The substrate 202 may include a single crystalline semiconductor material such as, but not limited to Si, Ge, SiGe, GaAs, InSb, GaP, GaSb, InAlAs, InGaAs, GaSbP, GaAsSb, and InP. The substrate 202 may include various doping configurations depending on circuit design. For example, different doping profiles, e.g., n-wells, p-wells, may be formed in the substrate 202 in regions designed for different device types, such as n-type field effect transistors (NFET), and p-type field effect transistors (PFET). In some embodiments, the substrate 202 may be a silicon-on-insulator (SOI) substrate including an insulator structure for enhancement.

In some embodiments, the fin structures 204 may be formed by depositing epitaxial semiconductor layers over the substrate 202 according to the device type to be formed. The fin structures 204 are then formed by lithography and etching processes using one or more patterning layers. In some embodiments, the fin structures 204 may include fin structures 204a for a first type of devices and fin structures 204b for a second type of devices.

Each of the fin structures 204a may include a well portion formed in a first well region of the substrate 202, and a fin portion formed from the epitaxially grown layer over the substrate 202. The fin portion may include epitaxially grown silicon germanium (SiGe), epitaxially grown silicon (Si), or other epitaxially grown semiconductor materials, such as germanium (Ge), a compound semiconductor such as SiC, GeAs, GaP, InP, InAs, and/or InSb, an alloy semiconductor such as GaAsP, AllnAs, AlGaAs, InGaAs, GalnP, and/or GalnAsP, or combinations thereof. In some embodiments, the fin structures 204a are configured to function of channel regions for N-type devices. The well portion may include pure silicon, or silicon with p-type dopants. The fin portion of the fin structures 204a may include epitaxially grown semiconductor material with tensile stress, such as SiP for NMOS.

Each of the fin structures 204b may include a well portion formed in a second well region of the substrate 202, and a fin portion formed from the epitaxially grown layer over the substrate 202. The fin portion may include epitaxially grown Si, epitaxially grown SiGe, or other epitaxially grown semiconductor materials, such as Ge, a compound semiconductor such as SiC, GeAs, GaP, InP, InAs, and/or InSb, an alloy semiconductor such as GaAsP, AllnAs, AlGaAs, InGaAs, GalnP, and/or GalnAsP, or combinations thereof. In some embodiments, the fin structures 204b are configured to function of channel regions for P-type devices. In some embodiments, the well portion may be pure silicon. In other embodiments, the well portion may be formed in a n-well and includes n-type dopants. The fin portion of the fin structures 204b may include epitaxially grown semiconductor material with compressive stress, such as epitaxially grown SiGe.

The fin structures 204 extend from the substrate 202 forming trenches between neighboring fins. As shown in FIG. 2, trenches 206 are formed between neighboring fin structures 204. In some embodiments, the fin structures 204 are parallelly arranged and has a pitch PI. In some embodiment, the pitch PI is in a range between about 10 nm and about 32 nm. As shown in FIG. 2, the fin structures 204 have a width W1 along the y direction and the trenches 206 have a spacing P along the y-direction. In some embodiments, the width W1 is in a range between about 4 nm and about 8 nm. In some embodiments, the spacing P is in a range between about 6 nm and about 24 nm. In some embodiments, a ratio of the spacing P over the width W1 is in a range between about 1.1 and about 6.0.

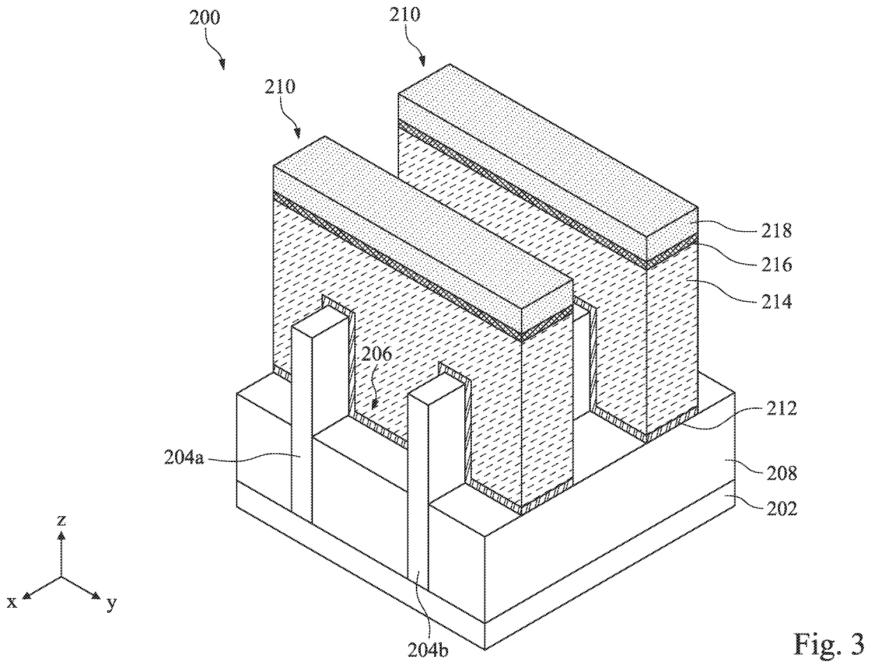

In operation 104, isolation layer 208 is formed in trenches 206 between the fin structures 204, as shown in FIG. 3. FIG. 3 is a schematic perspective view of the semiconductor device 200 after operation 104.

The isolation layer 208 is formed in the trenches between the fin structures 204 by a suitable deposition followed by an etch back process. The bottom profile of the isolation layer 208 is shown to be curved as an example. The isolation layer 208 may be formed by a high-density plasma chemical vapor deposition (HDP-CVD), a flowable CVD (FCVD), or other suitable deposition process. In some embodiments, the isolation layer 208 may include silicon oxide, silicon nitride, silicon oxynitride, fluorine-doped silicate glass (FSG), a low-k dielectric, or combinations thereof. In some embodiments, the isolation layer 208 may be formed by conformally deposit one or more layers of isolation material to fill the trenches 206. The one or more layers of the isolation material are then etched back to expose upper portions or fin portions of the fin structures 204. The isolation layer 208 fills lower portions of the trenches 206.

At operation 106, sacrificial gate structures 210 are formed over the isolation layer 208 and around the exposed portions of the fin structures 204a, 204b, as shown in FIG. 3. The sacrificial gate structures 210 are formed over portions of the fin structures 204a, 204b which are to be channel regions. The sacrificial gate structures 210 are substantially perpendicular to the fin structures 204. The sacrificial gate structures 210 may include a sacrificial gate dielectric layer 212, a sacrificial gate electrode layer 214, a pad layer 216, and a mask layer 218.

The sacrificial gate dielectric layer 212 may be formed conformally over the fin structures 204a, 204b, and the isolation layer 208. In some embodiments, the sacrificial gate dielectric layer 212 may be deposited by a CVD process, a sub-atmospheric CVD (SACVD) process, a FCVD process, an ALD process, a PVD process, or other suitable process. The sacrificial gate dielectric layer 212 may include one or more layers of dielectric material, such as SiO₂, SiN, a high-k dielectric material, and/or other suitable dielectric material.

The sacrificial gate electrode layer 214 may be blanket deposited on the over the sacrificial gate dielectric layer 212. The sacrificial gate electrode layer 214 includes silicon such as polycrystalline silicon or amorphous silicon. The thickness of the sacrificial gate electrode layer is in a range between about 42 nm and about 200 nm. In some embodiments, the sacrificial gate electrode layer 214 is subjected to a planarization operation. The sacrificial gate electrode layer 214 may be deposited using CVD, including LPCVD and PECVD, PVD, ALD, or other suitable process.

Subsequently, the pad layer 216 and the mask layer 218 are formed over the sacrificial gate electrode layer 214. The pad layer 216 may include silicon nitride. The mask layer 218 may include silicon oxide. Next, a processing sequence including patterning and etching is performed on the mask layer 218, the pad layer 216, the sacrificial gate electrode layer 214 and the sacrificial gate dielectric layer 212 to form the sacrificial gate structures 210. Portions of the sacrificial gate electrode layer 214 and the sacrificial gate dielectric layer 212 are sequentially removed using patterns formed in the mask layer 218 to form the sacrificial gate structures 210. In some embodiments, the sacrificial gate electrode layer 214 is first etched using the sacrificial gate dielectric layer 212 as an etch stop layer. The sacrificial gate dielectric layer 212 is then electively removed from the fin structures 204 and from the isolation layer 208 to expose portion of the fin structures 204, as shown in FIG. 3.

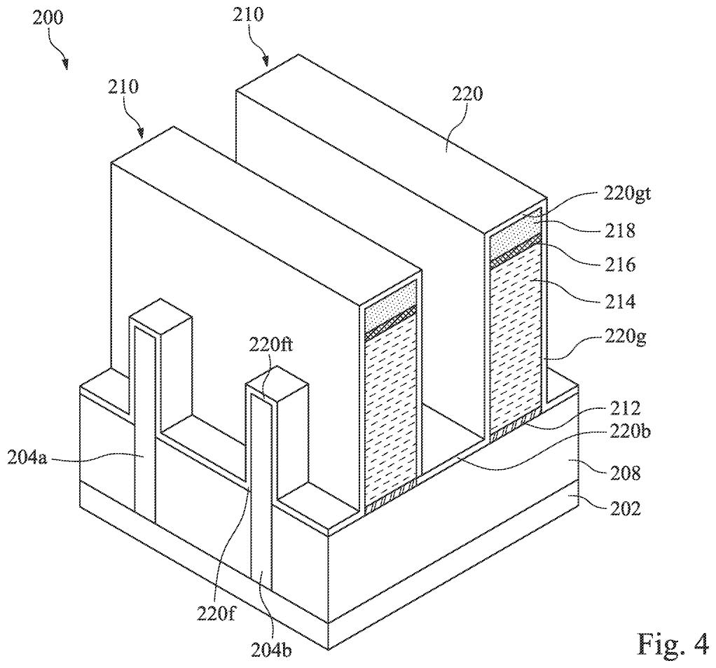

At operation 108, a spacer layer 220 is formed over the semiconductor device 200, as shown in FIG. 4, which is a schematic perspective view of the semiconductor device 200. After the sacrificial gate structures 210 are formed, the spacer layer 220 may be deposited over the semiconductor device 200 by a blanket deposition of one or more insulating material. Even though only one layer is shown in FIG. 4, the spacer layer 220 may include two or more layers of dielectric materials. In some embodiments, the spacer layer 220 may include one or more insulation material. The spacer layer 220 may include a silicon nitride-based material, such as SiN, SiON, SiOCN or SiCN and combinations thereof.

As shown in FIG. 4, the spacer layer 220 covers the sacrificial gate structures 210, the fin structures 204a, 204b, and the isolation layer 208. For clarity of description, portions of the spacer layer 220 formed on sidewalls of the sacrificial gate structures 210 are referred to as gate sidewall spacers 220g, portions of the spacer layer 220 formed on sidewalls of the fin structures 204a, 204b are referred to as fin sidewall spacers 220f, portions of the spacer layer formed on the isolation layer 208 are referred to as bottom spacers 220b, portions of the portions of the spacer layer 220 formed on top surfaces of the sacrificial gate structures 210 are referred gate top spacers 220gt, and portions of the portions of the spacer layer 220 formed on top surfaces 210t of the fin structures 204a, 204b are referred fin top spacers 220ft.

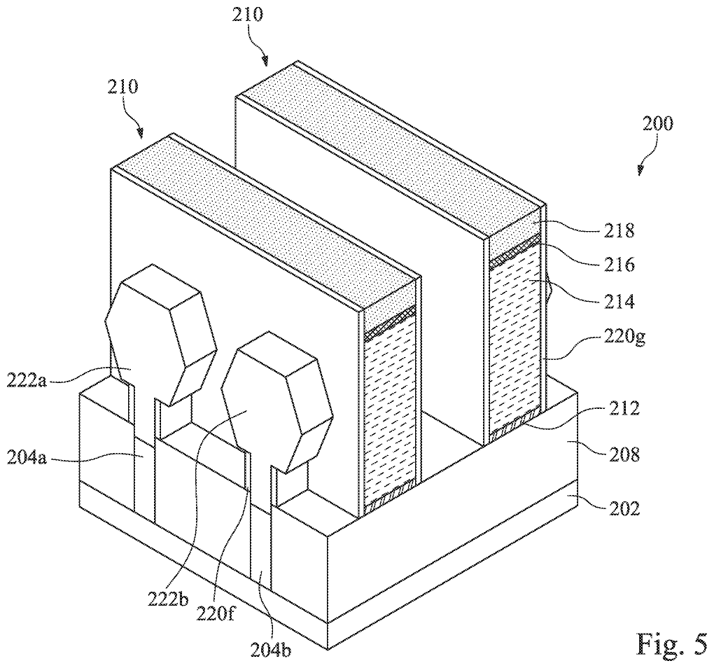

In operation 110, epitaxial source/drain regions 222a, 222b (collectively 222) are formed, as shown in FIG. 5, which is a schematic perspective view of the semiconductor device 200. The fin structures 204 in regions not covered by the sacrificial gate structures 210 and gate sidewall spacers 220g are first recess etched to form source/drain recesses. The bottom spacers 220b, the gate top spacers 220gt, the fin top spacers 220ft, and portions of the fin sidewall spacers 220f are removed during etch back of the fin structures 204. In some embodiments, suitable dry etching and/or wet etching may be used to remove the semiconductor material in the fin structures 204. In some embodiments, the fin structures 204a, 204b are recessed to a level below the isolation layer 208.

The epitaxial source/drain regions 222 are then formed in the source/drain recesses. The epitaxial source/drain regions 222 may be formed by any suitable method, such as by CVD, CVD epitaxy, molecular beam epitaxy (MBE), or any suitable deposition technique. The epitaxial source/drain regions 222 may be grown in an epitaxial chamber by a suitable process. For example, the epitaxial source/drain regions 222 are formed by a selective etching growth process, in which a thin film is deposited by introducing a reactant gas including deposition agent and etchant together. In some embodiments, an optional etching process may be performed to achieve desired shape and/or thickness of the epitaxial layer being formed.

The epitaxial source/drain regions 222 may include one or more layers of Si, SiP, SiC and SiCP for n-type device or Si, SiGe, Ge for p-type devices. For n-type devices, the epitaxial source/drain regions 222 also include n-type dopants, such as phosphorus (P), arsenic (As), etc. For p-type devices, the epitaxial source/drain regions 222 include p-type dopants, such as boron (B). The epitaxial source/drain regions 222a, 222b may be formed separately using masks and suitable patterning processes.

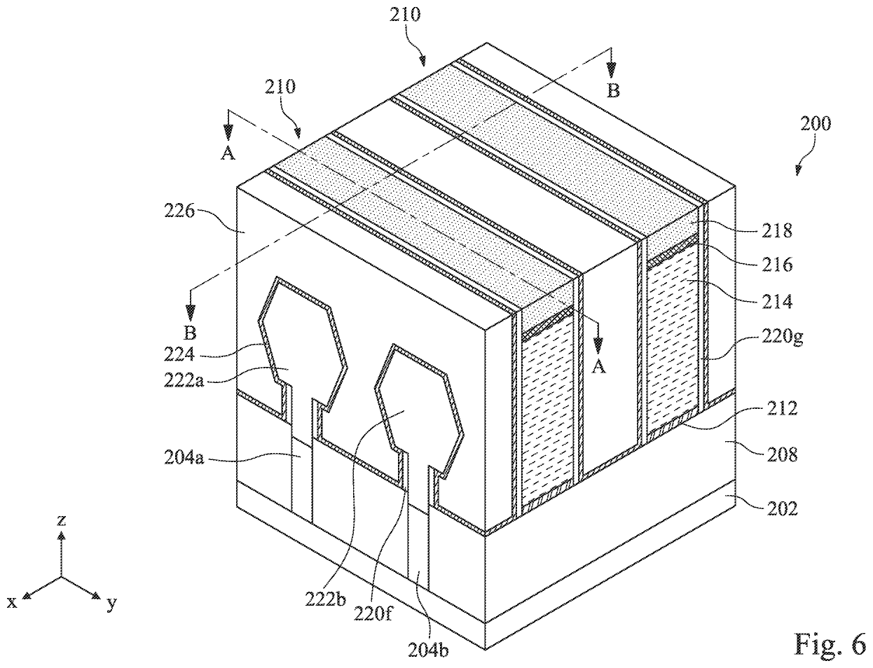

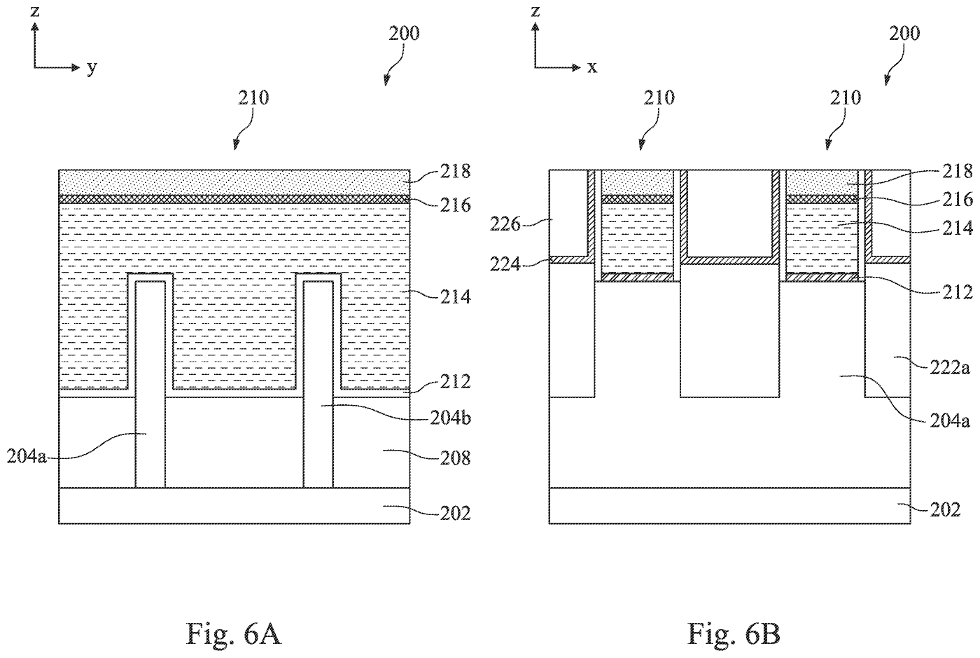

At operation 112, a contact etch stop layer (CESL) 224 and an interlayer dielectric (ILD) layer 226 are formed over the semiconductor device 200, as shown in FIGS. 6 and 6A-6B. FIG. 6 is a schematic perspective view of the semiconductor device 200. FIG. 6A is a schematic cross-sectional view of the semiconductor device 200 along the line A-A of FIG. 6. FIG. 6B is a schematic cross-sectional view of the semiconductor device 200 along the line B-B of FIG. 6. The CESL 224 is conformally formed over exposed surfaces of the semiconductor device 200. The CESL 224 is formed on the epitaxial source/drain regions 222, the sidewall spacers 220, and the isolation layer 208 if exposed. The CESL 224 may include SiN, SiON, SiCN or any other suitable material, and may be formed by CVD, PVD, or ALD.

The ILD layer 226 is formed over the CESL 224. The materials for the ILD layer 226 include compounds comprising Si, O, C, and/or H, such as silicon oxide, SiCOH and SiOC. Organic materials, such as polymers, may be used for the ILD layer 226. In some embodiments, the ILD layer 226 may be formed by flowable CVD (FCVD). The ILD layer 226 protects the epitaxial source/drain regions 222 during the removal of the sacrificial gate structures 210.

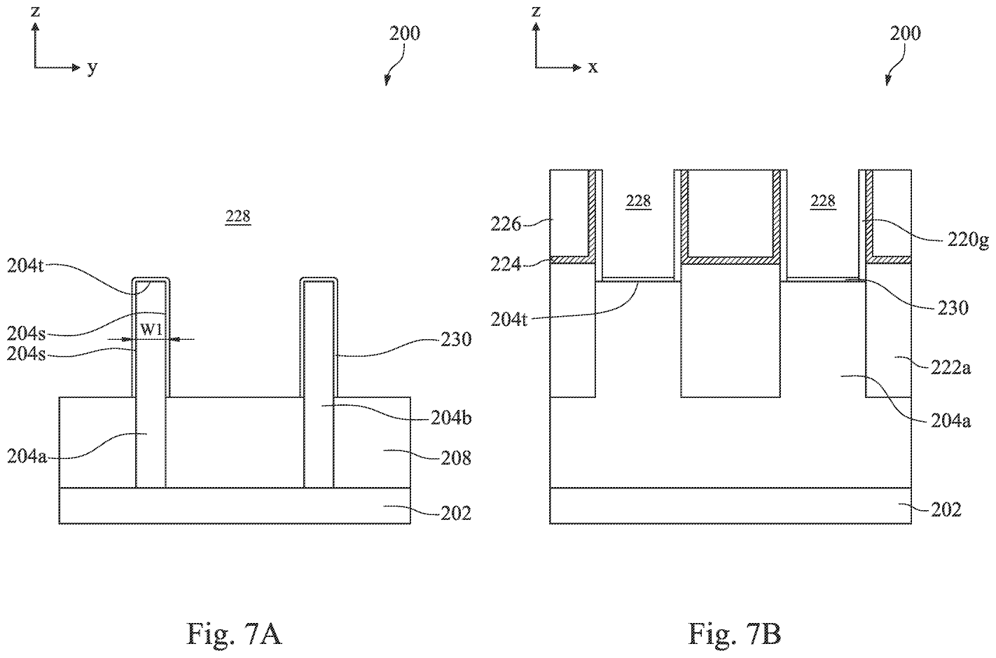

At operation 114, the sacrificial gate structures 210 are removed, as shown in FIGS. 7A and 7B. FIG. 7A is a cross sectional view of the semiconductor device 200 along the line A-A in FIG. 6. FIG. 7B is a cross sectional view of the semiconductor device 200 along the line B-B in FIG. 6. The sacrificial gate structures 210 are removed to form gate cavities 228 and expose the fin structures 204 so that replacement gate structures can be formed in the gate cavities 228.

The mask layer 218, the pad layer 216, the sacrificial gate electrode layer 214, and the sacrificial gate dielectric layer 212 may be sequentially removed by one or more suitable processes, such as dry etch, wet etch, or a combination thereof, to expose the fin structures 204. In some embodiments, a wet etchant such as a tetramethylammonium hydroxide (TMAH) solution is used. After operation 114, sidewalls 204s and a top surface 204t of each fin structures 204 are exposed to the gate cavity 228.

At operation 116, an interfacial dielectric layer 230 is formed over the fin structure 204, as shown in FIGS. 7A and 7B. The interfacial dielectric layer 230 may be formed on exposed surfaces of the fin structures 204. As shown in FIGS. 7A-7B, the interfacial dielectric layer 230 may be formed over the sidewalls 204s and the top surface 204t of the fin structures 204. In some embodiments, the interfacial dielectric layer 230 is substantially conformally formed on the sidewalls 204s and the top surface 204t of the fin structures 204.

The interfacial dielectric layer 230 may an ultra-thin interfacial dielectric layer, meaning that the interfacial dielectric layer 230 has a thickness in a range between about 5 angstroms and about 15 angstroms, for example, the interfacial dielectric layer 230 has a thickness less than or equal to about 10 angstroms.

The interfacial dielectric layer 230 may be an oxide-containing layer, such as a silicon oxide (SiO₂) layer or a silicon oxynitride (SiON) layer. The interfacial dielectric layer 230 may be formed by a chemical oxide technique, thermal oxide technique, atomic layer deposition (ALD), chemical vapor deposition (CVD), or other suitable technique. In some embodiments, the interfacial dielectric layer 230 includes at least one of HfSiO or SiON formed by at least one of atomic layer deposition (ALD), CVD, PVD, thermal oxidation and nitridation, plasma oxidation or nitridation. In some embodiments, an Hf film is formed on a thermal oxide by ALD, CVD, or PVD, and then oxidized by thermal O₂ to form HfSiO. In some embodiments, an Hf film is formed by ALD, CVD, or PVD in a reactive O₂ and H₂O ambient. In some embodiments, a cleaning process, such as a cleaning process using a hydrofluoric (HF) acid solution, may be performed before the interfacial dielectric layer 230 is formed over the fin structures 204.

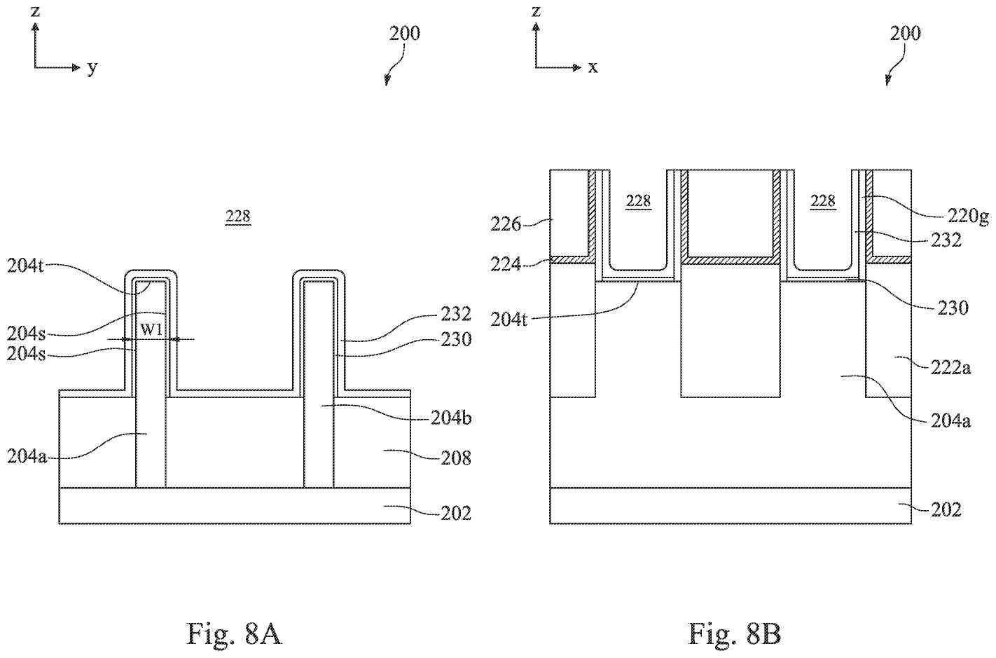

In operation 118, a gate dielectric layer 232 is formed over the fin structures 204, as shown in FIGS. 8A-8B. FIG. 8A is a cross sectional view of the semiconductor device 200 along the line A-A in FIG. 6. FIG. 8B is a cross sectional view of the semiconductor device 200 along the line B-B in FIG. 6.

The gate dielectric layer 232 is disposed over the interfacial dielectric layer 230, and the other exposed surface, such as the isolation layer 208. The gate dielectric layer 232 may be conformally deposited on exposed surfaces in the gate cavities 228. The gate dielectric layer 232 may have a thickness in a range between about 5 angstroms and about 30 angstroms according to device design.

The gate dielectric layer 232 may include one or more layers of a dielectric material, such as silicon oxide, silicon nitride, or high-k dielectric material, other suitable dielectric material, and/or combinations thereof. In some embodiments, the gate dielectric layer 232 includes hafnium oxide (HfO2). In other embodiments, the gate dielectric layer 232 includes Hf—X—O material, where X is silicon or metal, such as hafnium silicon oxide (HfSiO), hafnium silicon oxynitride (HfSiON), hafnium tantalum oxide (HMO), hafnium titanium oxide (HfTiO), or hafnium zirconium oxide (HfZrO); hafnium dioxide-alumina (HfO2-Al2O3) alloy; zirconium oxide (ZrO2); Zr—X—O material, where X is silicon or metal, such as zirconium silicate (ZrSiO4) or zirconium aluminate (ZrAlO); titanium oxide (TiO₂); Ti—X—O, where X is silicon or metal; lanthanum oxide (La₂O₃); La—X—O material, where X is silicon or metal; rare-earth oxide; other suitable high-k dielectric material; or combinations thereof.

The gate dielectric layer 232 may be formed by a suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, other suitable processes, or combinations thereof.

The gate dielectric layer 232 may have different composition and dimensions for N-type devices and P-type devices and are formed separately using patterned mask layers and different deposition recipes. The gate dielectric layer 232 may be formed by CVD, ALD, or any suitable method.

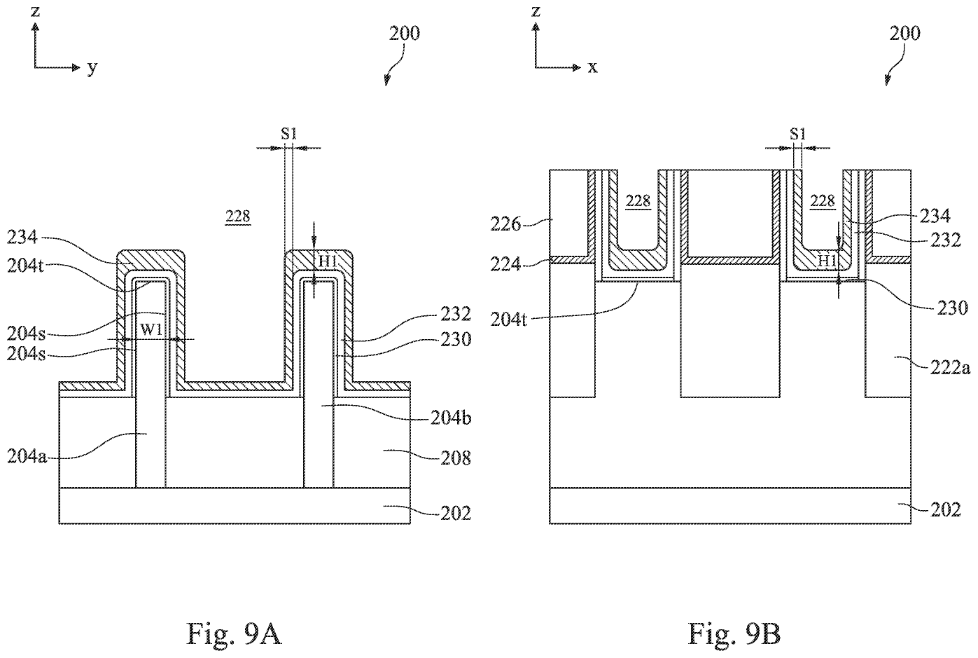

In operation 120, a first work function metal layer 234 is formed over the gate dielectric layer 232, as shown in FIG. 9A-9B. FIG. 9A is a cross sectional view of the semiconductor device 200 along the line A-A in FIG. 6. FIG. 9B is a cross sectional view of the semiconductor device 200 along the line B-B in FIG. 6.

The first work function metal layer 234 is disposed over the gate dielectric layer 232. In some embodiments, the first work function metal layer 234 may include material configured to scavenge impurity atoms, such as oxygen impurities, from the interfacial dielectric layer 230.

In some embodiments, the first work function metal layer 234 includes a titanium-rich or tantalum-rich material. For example, the first work function metal layer 234 includes a transition metal nitride, such as titanium nitride (TiN) or a transition metal carbide, such as tantalum carbide (TaC). The first work function metal layer 234 is metal rich, for example titanium rich or tantalum rich, because if the metal to nitrogen or carbon ratio is greater than one. In some embodiments, the first work function metal layer 234 is a titanium rich TiN layer having a Ti:N ratio in a range between about 1.05:1 and about 2:1. In other embodiments, the first work function metal layer 234 is a tantalum-rich TaC layer having a Ta:C ratio in a range between about 1.05:1 and about 2:1. Alternatively, the first work function metal layer 234 may include a reactive metal material to facilitate scavenging of impurity atoms from the dielectric layers, such as hafnium (Hf), titanium (Ti), cobalt (Co), aluminum (AI), zirconium (Zr), lanthanum (La), magnesium (Mg), other reactive metal, or combinations thereof. In some embodiments, the reactive metal material is a material capable of reacting with oxygen.

In some embodiments, the first work function metal layer 234 is a non-formal layer. Particularly, the first work function metal layer 234 has non-uniform thickness. In some embodiments, the first work function metal layer 234 has a sidewall thickness S1 along the sidewalls 204s of the fin structures 204 and a horizontal thickness H1 over the top surface 204t of the fin structures 204. The sidewall thickness S1 is different from the horizontal thickness H1. Particularly, the horizontal thickness H1 is greater than the sidewall thickness S1. In some embodiments, a ratio of the horizontal thickness H1 over the sidewall thickness S1 is in a range between about 1.1 and about 1.5. In some embodiments, the sidewall thickness S1 is in a range between about a thickness of about 5 angstroms to about 30 angstroms according to device design.

With a greater horizontal thickness H1, the first work function metal layer 234 is thicker at the top of the fin structure 204. Because top portions of the fin structures 204 would sustain more exposure to process environment than sidewall portions of the fin structures 204 during subsequent processing, thicker first work function metal layer 234 over the top surface 204t would avoid being damaged and leading to leaks. Thinner portion of the first work function metal layer 234 on the sidewalls 204s of the fin structures 204 leave additional space in the gate cavity 228 between the fin structures 204 for low resistance conductive material, thus, improving device performance. Additionally, because of the geometric shape of the fin structures 204, current density is higher near the top surface 204t of the fin structures 204 during operation of the semiconductor device 200, greater thickness of the first work function metal layer 234 can provide better leakage control around the top portions of the fin structures 204. A thicker work functional metal layer 234 on the top surface make it easier to turn on device because higher carrier density at top at on-state. Therefore, a thicker work functional metal layer 234 on the fin top can improve device performance. Additionally, a thicker work functional metal layer 234 on fin top area makes it more difficult for oxygen to diffuse into the interfacial layer and the gate dielectric layer, therefore, preventing re-growth of the interfacial layer and resulting in lower oxide thickness to improve device performance. On off-state, current leakage mainly comes from center portion of the fin. If the work function metal layer 234 is thinner on the sidewalls 204s, the sidewall area will need a larger threshold voltage Vt to turn on. Therefore, a thinner work function metal layer 234 on the sidewalls 204s can also help reduce leakage current on off-state.

In some embodiments, the first work function metal layer 234 may be formed by ALD. In some embodiments, the non-conformal thickness of the first work function metal layer 234 may be achieved by adjusting processing pressure and or pulse duration of precursors during ALD process. In some embodiments, the processing pressure of the ALD process may be reduced to a level of between about 40% and about 60% of the pressure level for a conformal deposition to achieve a greater horizontal thickness H1. In other embodiments, the precursor injection pulse of the ALD process may be reduced to a length of between about 30% and about 70% of the pulse length for a conformal deposition to achieve a greater horizontal thickness H1.

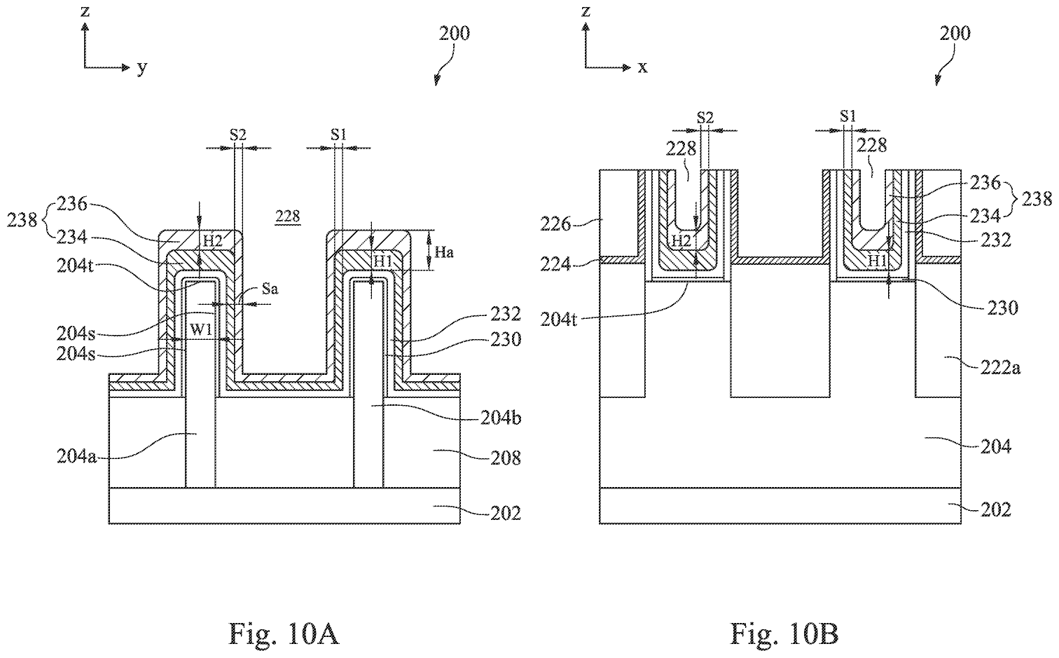

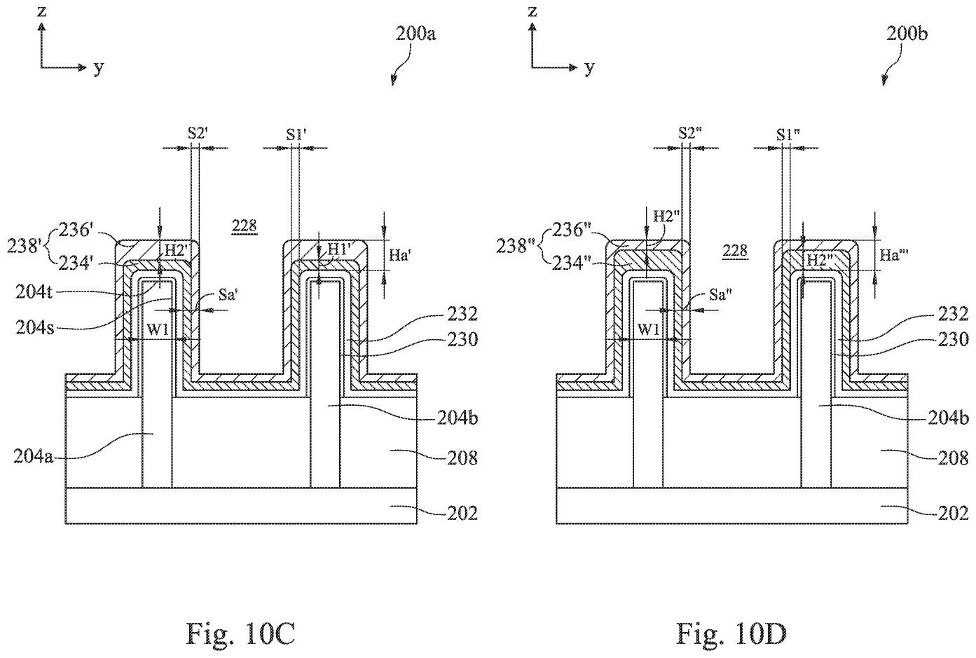

In operation 122, a second work function metal layer 236 is formed over the first work function metal layer 234, as shown in FIG. 10A-10B. FIG. 10A is a cross sectional view of the semiconductor device 200 along the line A-A in FIG. 6. FIG. 10B is a cross sectional view of the semiconductor device 200 along the line B-B in FIG. 6.

The second work function metal layer 236 is disposed over the first work function metal layer 234. The second work function metal layer 236 may function as a barrier layer. In some embodiments, the second work function metal layer 236 may include material configured to prevent small metal element, such as aluminum, in subsequent film from diffusing into the gate dielectric layer 232. In some embodiments, the second work function metal layer 236 is a multi-metal layer structure. The second work function metal layer 236 is at least one of tungsten nitride (WN), tantalum nitride (TaN) or ruthenium (Ru). In some embodiments, the second work function metal layer 236 comprises TaN, for example for N-type devices. In some embodiments, the second work function metal layer 236 is titanium nitride/tungsten nitride (TiN/WN), for example for P-type devices.

In some embodiments, the second work function metal layer 236 is a non-formal layer. Particularly, the second work function metal layer 236 has non-uniform thickness. In some embodiments, the second work function metal layer 236 has a sidewall thickness S2 along the sidewalls 204s of the fin structures 204 and a horizontal thickness H2 over the top surface 204t of the fin structures 204. The sidewall thickness S2 is different from the horizontal thickness H2. Particularly, the horizontal thickness H2 is greater than the sidewall thickness S2. In some embodiments, a ratio of the horizontal thickness H2 over the sidewall thickness S2 is in a range between about 1.1 and about 1.5. In some embodiments, the sidewall thickness S2 is in a range between about a thickness of about 10 angstroms to about 50 angstroms according to device design.

With a greater horizontal thickness H2, the second work function metal layer 236 is thicker at the top of the fin structure 204. Because top portions of the fin structures 204 would sustain more exposure to process environment than sidewall portions of the fin structures 204 during subsequent processing, thicker second work function metal layer 236 over the top surface 204t would avoid being damaged and leading to leaks. Thinner portion of the second work function metal layer 236 on the sidewalls 204s of the fin structures 204 leave additional space in the gate cavity 228 between the fin structures 204 for low resistance conductive material, thus, improving device performance. Additionally, because of the geometric shape of the fin structures 204, current density is higher near the top surface 204t of the fin structures 204 during operation of the semiconductor device 200, greater thickness of the second work function metal layer 236 can provide better leakage control around the top of the fin structure 204. A thicker second work function metal layer 236 near the top surface 204t makes it easier to turn on device because higher carrier density at the fin top at on-state. Therefore, a thicker second work function metal layer 236 near the top surface 204t can improve device performance. Additionally, a thicker second work function metal layer 236 near the top surface 204t can prevent anisotropic process damage and makes it different for Al atom to be driven into the interfacial layer and the high-k dielectric layer. At off-state, current leakage mainly comes from center region of the fin. If the work function metal layer 236 in thinner near the sidewall 204s of the fin, the sidewall area may need a larger threshold voltage Vt to turn on, thus, it reducing leakage current on off-state.

In some embodiments, the second work function metal layer 236 may be formed by ALD, CVD, or PVD. In some embodiments, the non-conformal thickness of the second work function metal layer 236 may be achieved by adjusting processing pressure and or pulse duration of precursors during ALD process. In some embodiments, the processing pressure of the ALD process may be reduced to a level of between about 50% and about 60% of the pressure level for a conformal deposition to achieve a greater horizontal thickness H2. In other embodiments, the precursor injection pulse of the ALD process may be reduced to a length of between about 30% and about 70% of the pulse length for a conformal deposition to achieve a greater horizontal thickness H2.

As shown in FIGS. 10A-10B, the first work function metal layer 234 and the second work function metal layer 236 form a combined non-conformal layer 238 which has a horizontal thickness Ha and a sidewall thickness Sa. The horizontal thickness Ha is greater than the sidewall thickness Sa. In some embodiments, a ratio of the sidewall thickness Sa of the combined non-conformal layer 238 over the width W1 of the fin structures 204 is in a range between about 0.5 and about 1.0. A ratio of the horizontal thickness Ha over the sidewall thickness Sa is in a range between about 1.1 and about 1.5.

The dimensions of the combined non-conformal layer 238 may be achieved by adjusting dimensions of the first work function metal layer 234 and the second work function metal layer 236. In the embodiment shown in FIGS. 10A-10B, both the first work function metal layer 234 and the second work function metal layer 236 are non-conformal layers. Alternatively, only one of the first work function metal layer 234 and the second work function metal layer 236 is non-conformal.

FIG. 10C is a schematic sectional view of a semiconductor device 200a according to another embodiment of the present disclosure. The semiconductor device 200a is similar to the semiconductor device 200 except that the semiconductor device 200a includes a first work function metal layer 234′ and a second work function metal layer 236′. The first work function metal layer 234′ is conformal and the second work function metal layer 236′ is non-conformal. The first work function metal layer 234′ and the second work function metal layer 236′ form a non-conformal combined layer 238′. The first work function metal layer 234′ has a sidewall thickness S1′ substantially the same as a horizontal thickness H1′. The second work function metal layer 236′ has a horizontal thickness H2′ greater than a sidewall thickness S2′. The non-conformal combined layer 238′ has a horizontal thickness Ha′ greater than a sidewall thickness Sa′.

FIG. 10D is a schematic sectional view of a semiconductor device 200b according to another embodiment of the present disclosure. The semiconductor device 200b is similar to the semiconductor device 200 except that the semiconductor device 200b includes a first work function metal layer 234″ and a second work function metal layer 236″. The first work function metal layer 234″ is non-conformal and the second work function metal layer 236″ is conformal. The first work function metal layer 234″ and the second work function metal layer 236″ form a combined non-conformal layer 238″. The first work function metal layer 234″ has a horizontal thickness H1″ greater than a sidewall thickness H1″. The second work function metal layer 236″ has a horizontal thickness H2″ substantially the same as a sidewall thickness S2″. The non-conformal combined layer 238″ has a horizontal thickness Ha″ greater than a sidewall thickness Sa″.

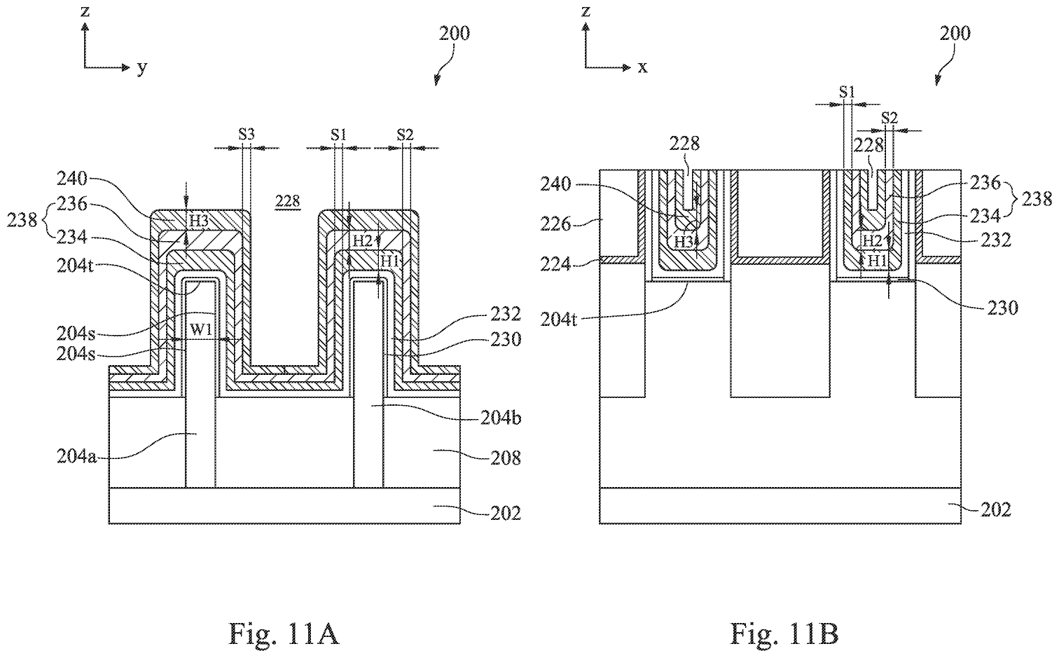

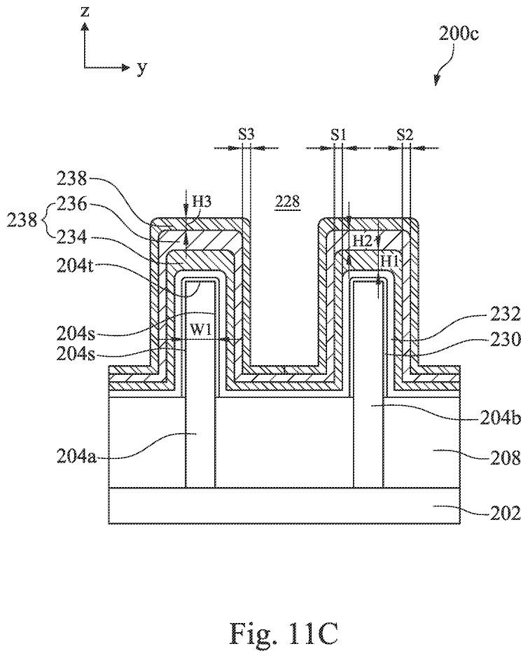

In operation 124, a third work function metal layer 240 is formed over the combined non-conformal layer 238, as shown in FIGS. 11A-11B. FIG. 11A is a cross sectional view of the semiconductor device 200 along the line A-A in FIG. 6. FIG. 11B is a cross sectional view of the semiconductor device 200 along the line B-B in FIG. 6.

The third work function metal layer 240 may include one or more conductive materials. In some embodiments, the third work function metal layer 240 is designed to tune and achieve a target threshold voltage. In some embodiment, the third work function metal layer 240 may include one or more layers of conductive material, such as Ag, Au, Al, Rh, W, Mo, Zn, Co, Ru, Nb, Ti, Ta, Zr, TiAl, TiAlN, metal compound/Alloy, such as TIN, brass, phosphor bronze, cast steel, and/or combinations thereof. In some embodiments, the third work function metal layer 240 may include a titanium aluminum (TiAl) layer or a titanium aluminum nitride (TiAlN) layer. The third work function metal layer 240 may be formed using ALD, CVD, or other suitable method.

In some embodiments, the third work function metal layer 240 is a non-formal layer. Particularly, the third work function metal layer 240 has non-uniform thickness. In some embodiments, the third work function metal layer 240 has a sidewall thickness S3 along the sidewalls 204s of the fin structures 204 and a horizontal thickness H3 over the top surface 204t of the fin structures 204. The sidewall thickness S3 is different from the horizontal thickness H3. Particularly, the horizontal thickness H3 is greater than the sidewall thickness S3. In some embodiments, a ratio of the horizontal thickness H3 over the sidewall thickness S3 is in a range between about 1.1 and about 1.8 based on the material type. In some embodiments, the sidewall thickness S3 is in a range between about a thickness of about 6 angstroms to about 50 angstroms.

With a greater horizontal thickness H3, the third work function metal layer 240 is thicker at the top of the fin structures 204. Because top portions of the fin structures 204 have higher current density than sidewalls, greater horizontal H3 thickness of the third work function metal layer 240 may be used to achieve ion current requirement with a lower threshold voltage. A lower threshold voltage has several benefits. For example, a lower threshold voltage corresponds to smaller electric field in the gate dielectric layer 232, thus, improving reliability. A lower threshold voltage also provides room for device boost using threshold voltage and ion tuning. Furthermore, a lower threshold voltage may reduce off state current (Ioff), thus, achieving better leakage control. I. Additionally thinner portions of the third work function metal layer 240 on the sidewalls 204s of the fin structures 204 leave additional space in the gate cavity 228 between the fin structures 204 for low resistance conductive material, thus, improving device performance.

The work function metal layers 234, 236, 240 for n-type FET and p-type FET may include different materials or have different combinations to achieve different threshold voltages. The work function metal layers for the n-type devices and p-type devices may be formed separately using one or more patterning processes.

Alternatively, the third work function metal layer 240 may be conformally formed over the sidewalls 204s and the top surface 204t of the fin structures 204. FIG. 11C is a schematic sectional view of a semiconductor device 200c according one embodiments of the present disclosure. The semiconductor device 200C is similar to the semiconductor device 200 except that the semiconductor device 200C includes a third work function metal layer 240′ having a conformal thickness around the fin structures 204.

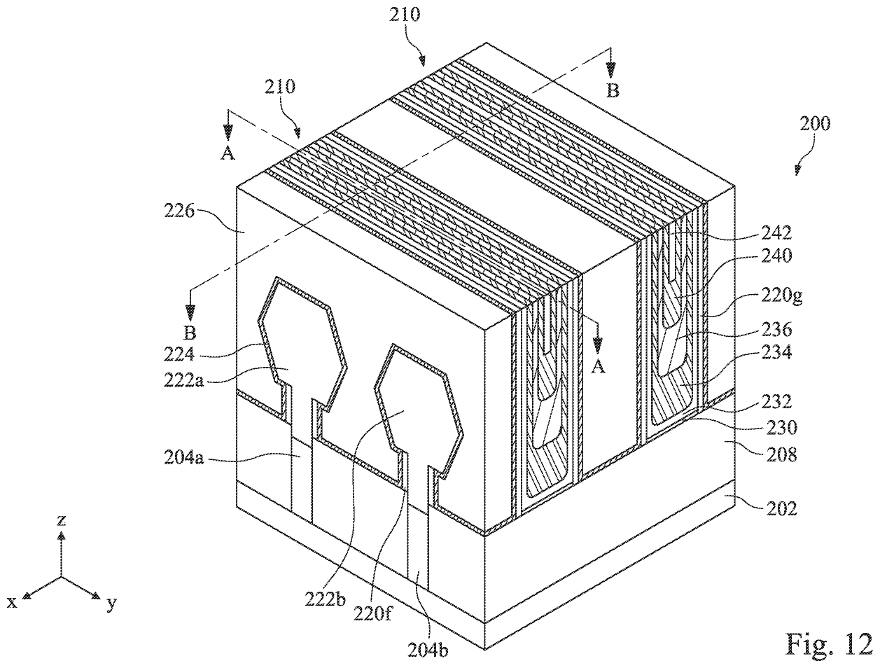

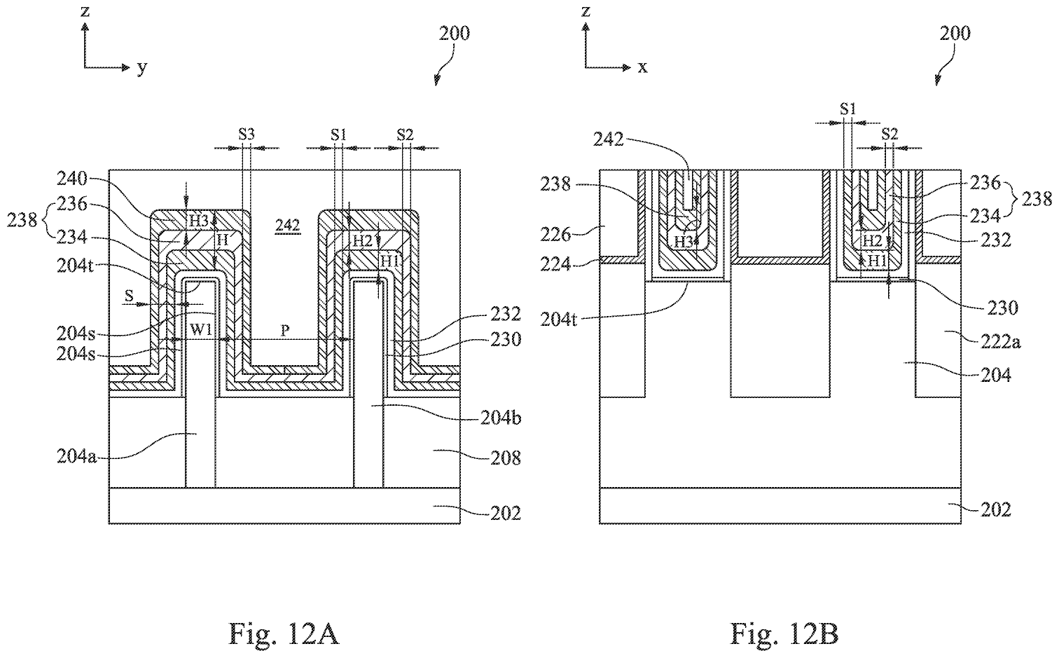

As shown in FIG. 12A, the first work function metal layer 234, the second work function metal layer 236, and the third work function metal layer 240 form a work function metal film stack, having a sidewall thickness S and a horizontal thickness H. The sidewall thickness S may be designed according to the width W1 of the fin structure 204. In some embodiments, a ratio of the sidewall thickness S over the fin width W1 may be in a range between about 0.5 and about 1.0. The horizontal thickness H is greater than the sidewall thickness S. In some embodiments, a ratio of the horizontal thickness H over the sidewall thickness S may be in a range between about 1.1 and about 1.5.

In operation 126, a gate fill layer 242 is formed in the gate cavities 228, as shown in FIGS. 12 and 12A-12B. FIG. 12 is a schematic perspective view of the semiconductor device 200. FIG. 12A is a cross sectional view of the semiconductor device 200 along the line A-A in FIG. 12. FIG. 12B is a cross sectional view of the semiconductor device 200 along the line B-B in FIG. 12.

The gate fill layer 242 is then formed the third work function metal layer 240 to fill the gate cavities 228. The gate fill layer 242 may include one or more layers of conductive material, such as tungsten, copper, aluminum, metal alloys, other suitable materials, and/or combinations thereof. In some embodiments, the gate fill layer 242 may be formed by CVD, ALD, electro-plating, or other suitable method. After the formation of the gate fill layer 242, a planarization process, such as a CMP process, is performed to remove excess deposition of the gate electrode material and expose the top surface of the ILD layer 226.

As descripted above, embodiments of the present disclosure provide a work function metal film stack that in non-conformal. Particularly, the non-conformality may be characterized in a greater thickness over a top surface of a fin structure and a smaller thickness along sidewalls of the fin structure. The non-conformality may be achieved by forming one or more non-conformal films in the work function metal film stack.

In the semiconductor device 200 described above, the work function metal film stack includes the first work function metal layer 234, the second work function metal layer 236, and the third work function metal layer 240. The first work function metal layer 234 includes a reactive metal material to facilitate scavenging of impurity atoms from the gate dielectric layers. The second work function metal layer 236 includes a barrier material configured to prevent diffusion of metal atoms from the third work function metal layer 240 into the gate dielectric layers. The third work function metal layer 240 functions to achieve a target threshold voltage. Depending on the design needs, one or more of the first work function metal layer 234, the second work function metal layer 236, and the third work function metal layer 240 may be formed non-conformally.

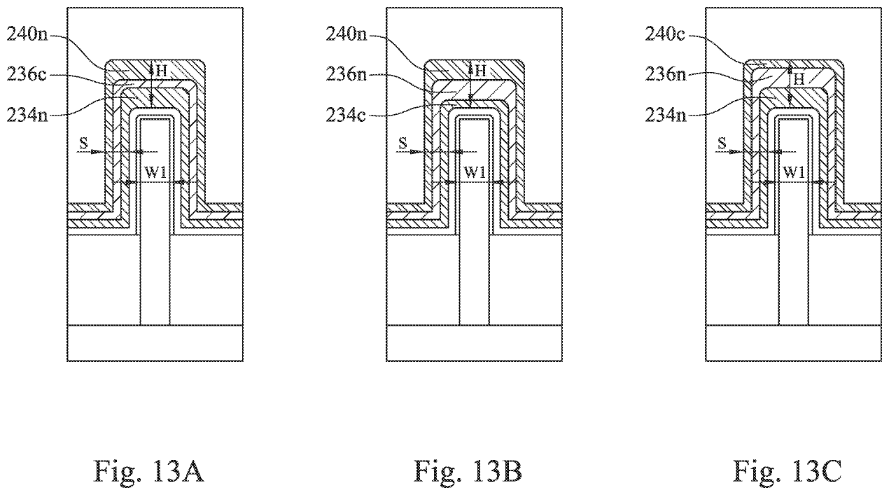

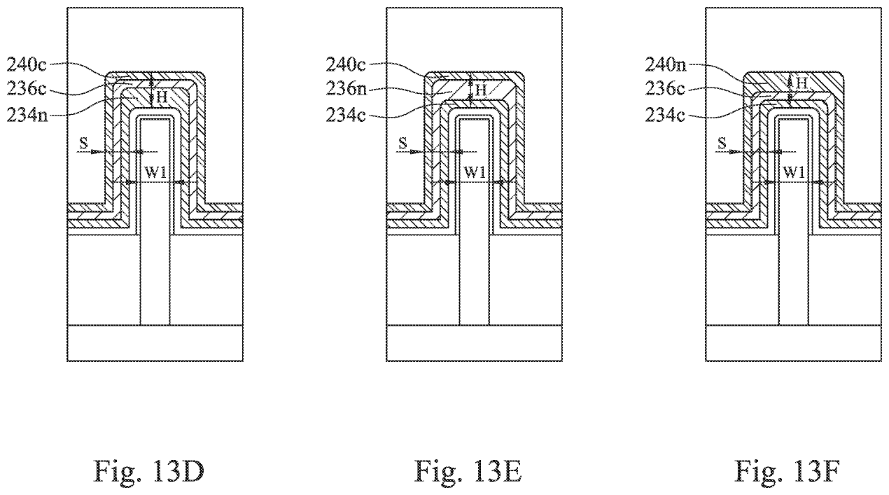

FIGS. 13A-13F schematically illustrate various work function metal film stack designs according to embodiments of the present disclosure. In FIGS. 13A-13F, various work function metal film stacks are formed from different combinations of conformal work function metal layer 234c, 236c, 240c and non-conformal work function metal layers 234n, 236n, 240n.

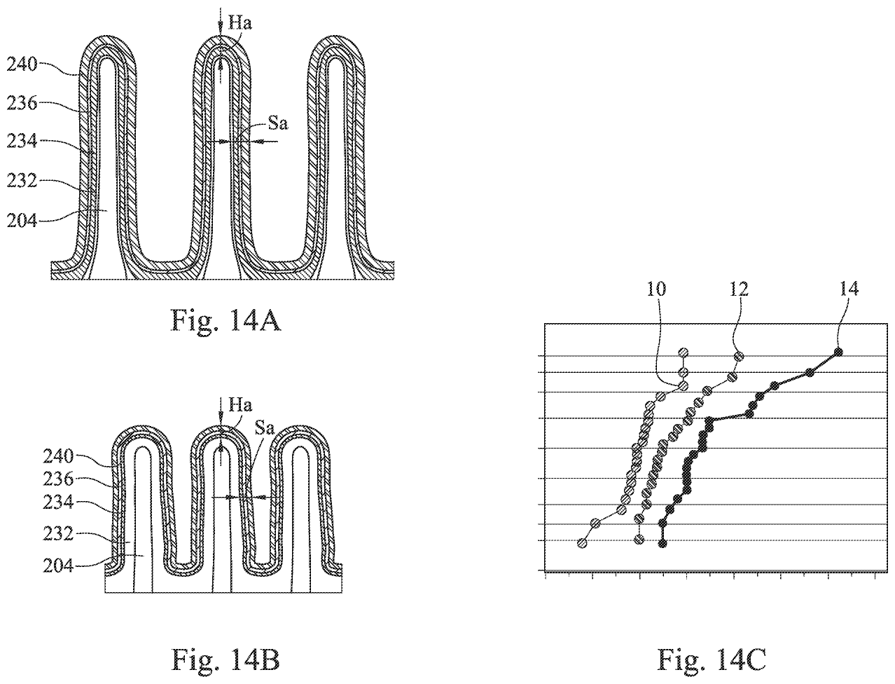

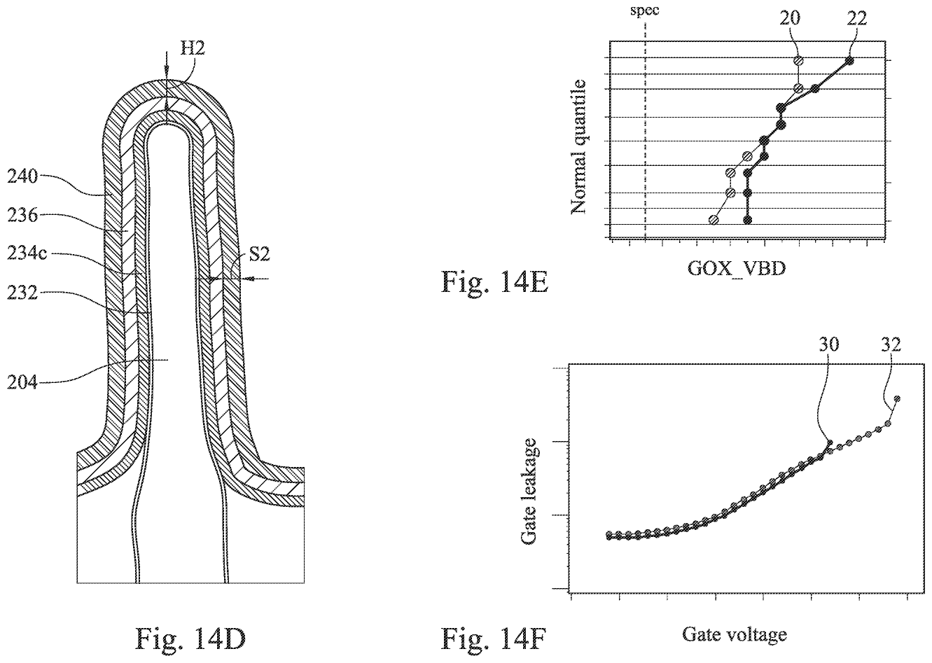

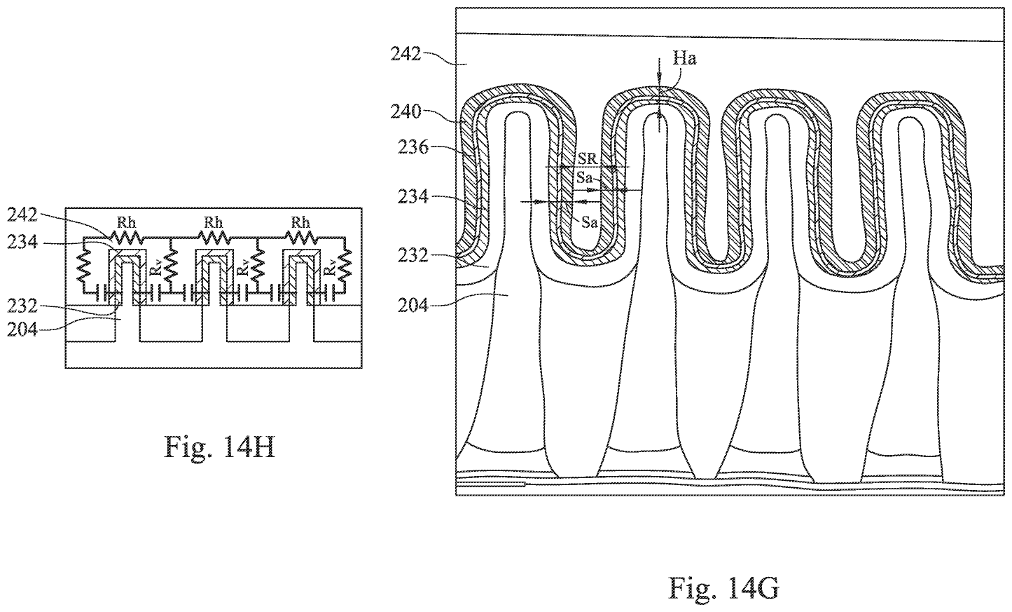

FIG. 14A is a transmission electron microscopy (TEM) image of a cross-section of an exemplary semiconductor device with a non-conformal work function metal layer according to the present disclosure. The semiconductor device shown in FIG. 14A is a core device having a thin gate dielectric layer. As shown in FIG. 14A, the first work function metal layer 234 and the second work function metal layer 236 form a combined non-conformal layer. The combined layer has a thickness Ha over tops of the fin structures 204 and a thickness Sa on sidewalls of the fin structures 204. In FIG. 14A, the ratio of thickness Ha over thickness Sa is in a range between 1.06 and 1.30.

FIG. 14B is a TEM image of a cross-section of an exemplary semiconductor device with a non-conformal work function metal layer according to the present disclosure. The semiconductor device shown in FIG. 14B is an I/O device having a thick gate dielectric layer. As shown in FIG. 14B, the first work function metal layer 234 and the second work function metal layer 236 form a combined non-conformal layer. The combined layer has a thickness Ha over tops of the fin structures 204 and a thickness Sa on sidewalls of the fin structures 204. In FIG. 14B, the ratio of thickness Ha over thickness Sa is in a range between 1.15 and 1.35.

FIG. 14C includes graphs showing profiles of work function metal layer over a semiconductor fin. The x-axis in FIG. 14C is a ratio of work function metal layer thickness on fin top over work function metal layer thickness on fin sidewalls. The y-axis of the FIG. 14C represent distance from a reference point near the middle of the semiconductor fin. In FIG. 14C, quantile-quantile plot is used to demonstrate the difference between embodiments of the present disclosure and existing technology. Curve 10 is a profile of a work function metal layer formed according to the current state of art. Curves 12 and 14 are profiles of work function metal layers formed according to present disclosure. Curves 12 and 14 show greater thickness of work function metal layer on top of the semiconductor fin. Curve14 is an optimize process and have more cycle times than Curve12, therefore, with an thickness increase for about 20-25%.

FIG. 14D is a TEM image of a cross-section of an exemplary semiconductor device with a non-conformal work function metal layer according to the present disclosure. The semiconductor device shown in FIG. 14D has a non-conformal second work function metal layer 236, which functions as a barrier layer. The second work function metal layer has a thickness H2 over the top of the fin structure 204 and a thickness S2 on sidewalls of the fin structure 204. In FIG. 14D, the ratio of thickness H2 over thickness S2 is about 1.39. The greater thickness of the second work function metal layer 236 increases breakdown voltage of the gate dielectric layer and maximum current without leakage. FIGS. 14E and 14F demonstrate the improved reliability for devices according to the present disclosure. includes graphs showing breakdown voltages. Curves 20, 22, and 30, 32 demonstrates that non-conformal WFM barrier have higher oxide breakdown voltage (from +0.1V in FIG. 14E to +0.6V in FIG. 14F) due to less aluminum atom diffusion into the high-k dielectric material.

FIG. 14G is an image of a cross-section of an exemplary semiconductor device with a non-conformal work function metal layer according to the present disclosure. FIG. 14G shows a plurality of fin structures 204. As shown in FIG. 14G, the first work function metal layer 234, the second work function metal layer 236, and a third work function metal layer 240 form a combined non-conformal layer. The combined layer has a thickness Ha over tops of the fin structures 204 and a thickness Sa on sidewalls of the fin structures 204. The non-conformal work function metal film stack results in an increased space SR between the fin structures 204, in which low resistance material or the gate fill layer 240 is formed. FIG. 14H includes a schematic equivalent circuit of the gate dielectric layer, the work function metal layer stack, and the gate fill layer around the fin structures. An increased volume between fin-fin space for the gate fill layer would reduce Rv, therefore, improving device performance.

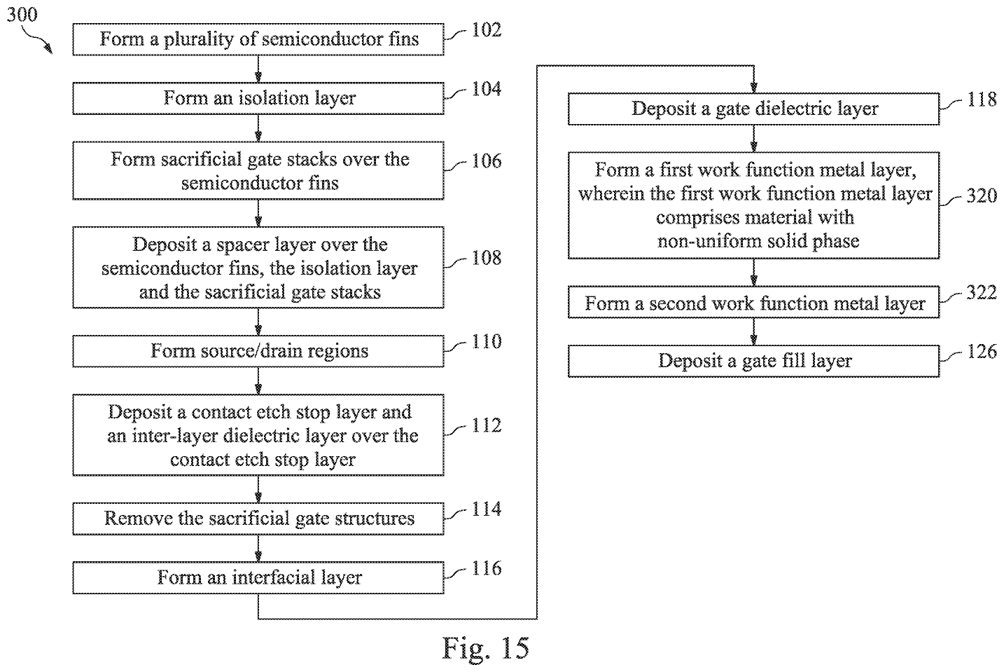

FIG. 15 is a flow chart of an exemplary method 300 for forming a semiconductor device according to embodiments of the present disclosure. The method 300 is similarly to the method 100 except instead of forming work function metal films with non-conformal thickness, the method 300 includes an operation to form a work function metal film stack with non-uniform solid phases. The method 300 includes operations 102-118, which are schematically illustrated and described in FIGS. 2 to 8A-8B.

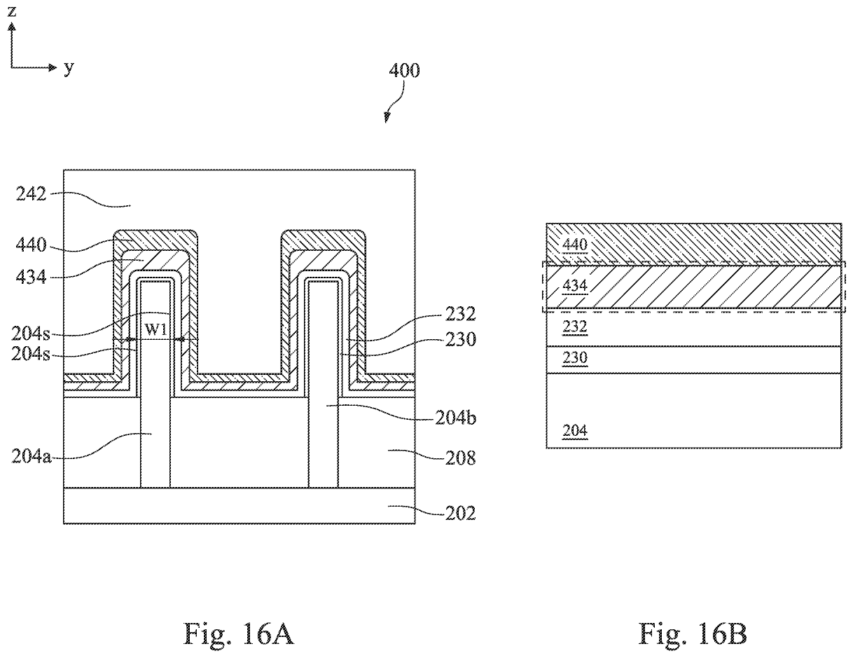

In operation 320, a first work function metal layer 434 is formed over the gate dielectric layer 232, as shown in FIG. 16A. The first work function metal layer 434 includes a portion of amorphous material to provide a superior diffusion barrier relative to a polycrystalline film. In some embodiments, the first work function metal layer 434 includes metal carbonitride (TaₓC_{y}N_{z} or TaCN), tungsten nitride (WN), tantalum nitride (TaN), ruthenium (Ru), titanium nitride/tungsten nitride (TiN/WN), and TiSiN (amorphous TiN doped with Si). The amorphous phase of the first work function metal layer 434 may be achieved by adjusting deposition temperature, pressure, or other process parameters. In some embodiments, the amorphous first work function metal layer 434 has a thickness in a range between about 5 angstroms and about 30 angstroms.

In operation 322, a second work function metal layer 440 is formed over the work function metal layer 434, as shown in FIG. 16A. The second work function metal layer 440 may include one or more conductive materials. In some embodiments, the second work function metal layer 440 is designed to tune and achieve a target threshold voltage. In some embodiment, the second work function metal layer 440 may include one or more layers of conductive material, such as Ag, Au, Al, Rh, W, Mo, Zn, Co, Ru, Nb, Ti, Ta, Zr, TiAl, TiAlN, metal compound/Alloy, such as TiN, brass, phosphor bronze, cast steel, and/or combinations thereof. In some embodiments, the second work function metal layer 440 second work function metal layer 440 may include a titanium aluminum (TiAl) layer or a titanium aluminum nitride (TiAlN) layer. The second work function metal layer 440 may be formed using ALD, CVD, or other suitable method. In some embodiments, the second work function metal layer 440 is a non-formal layer, as shown in FIG. 16A. Alternatively, the second work function metal layer 440 may be a conformal layer.

FIG. 16B schematically illustrates a work function metal film stack of the semiconductor 400. The amorphous first work function metal layer 434 prevents the metal atoms, such as aluminum, from diffusing through and into the gate dielectric layer 232.

In the embodiment of FIG. 16A, the first work function metal layer 434 includes a single layer of amorphous film. Alternatively, the first work function metal layer 434 may include one or more layers having other solid phases. For example, the first work function metal layer 434 may include layers or portions of material of other phases, such as polycrystalline phase, crystalline phase.

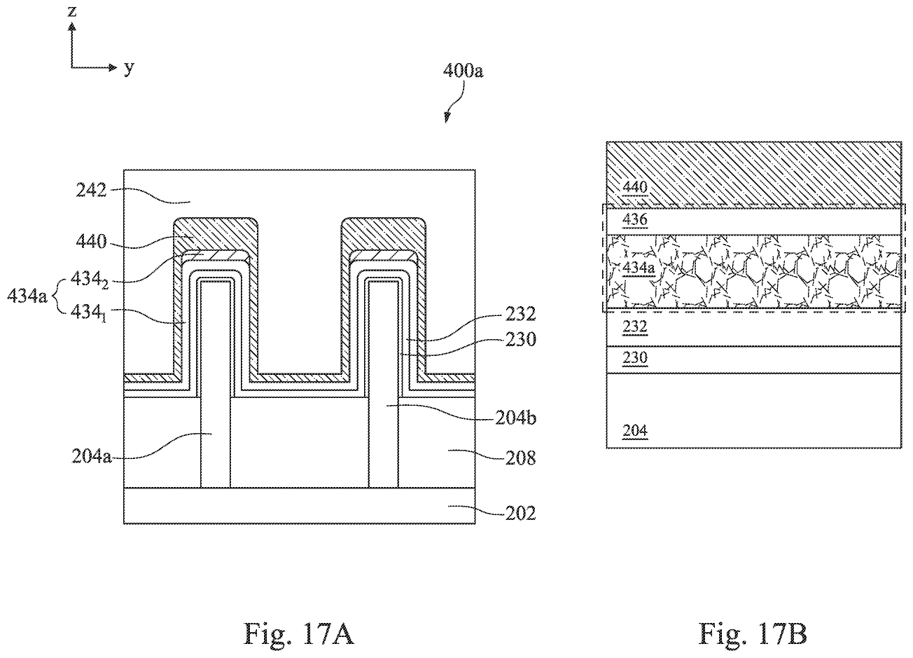

FIG. 17A schematically illustrates a semiconductor device 400a fabricated using the method 300. The semiconductor device 400a is similar to the semiconductor device 400 except that the semiconductor device 400a includes a first work function metal layer 434a having a polycrystalline portion 4341 and an amorphous portion 4342. In some embodiments, the polycrystalline portion 4341 may be formed over the gate dielectric layer 232. In some embodiments, the polycrystalline portion 4341 may have a conformal thickness. In other embodiments, the polycrystalline portion 4341 may have non-conformal thickness, for example thicker on the fin top and thinner on sidewalls of the fin structure 204. The amorphous portion 4342 is formed over the polycrystalline portion 4341. In some embodiments, the amorphous portion 4342 is formed over a portion of the polycrystalline portion 4341. For example, as shown in FIG. 17A, the amorphous portion 4342 is formed on the polycrystalline portion 4341 over the top surface 204t of the fin structure 204 but not on the polycrystalline portion 4341 over the sidewalls 204s of the fin structure 204. In some embodiments, the amorphous portion 4342 has a thickness in a range between about 3 angstroms and about 20 angstroms.

Alternatively, the amorphous portion 4342 is formed over the entire polycrystalline portion 4341. In some embodiments, the amorphous portion 4342 may be conformally formed over the entire polycrystalline portion 4341. In some embodiments, the amorphous portion 4342 may be non-conformally formed over the entire polycrystalline portion 4341, for example thicker above the fin top and thinner on the sidewalls.

FIG. 17B schematically illustrates a work function metal film stack of the semiconductor device 400a. The amorphous portion 4342 is disposed against the second work function metal layer 440 preventing metal atoms, such as aluminum, from diffusing through and into the gate dielectric layer 232.

Embodiments of the present disclosure provide a FinFET transistor having a gate structure including one or more non-conformal work function metal layers. In some embodiments, work function metal layers may be non-conformal in at least one of thickness, composition, and/or phases. The non-uniformity in the work function metal layer lowers leakage, improve device performance, and increase device reliability.

It will be understood that not all advantages have been necessarily discussed herein, no particular advantage is required for all embodiments or examples, and other embodiments or examples may offer different advantages.

Some embodiments of the present disclosure relate to a semiconductor device, comprising: a first source/drain region; a second source/drain region; a fin structure disposed between the first source/drain region and the second source/drain region; and a gate structure disposed over a top surface and sidewalls of the fin structure, wherein the gate structure comprises: a gate dielectric layer; and a work function metal film stack, wherein the work function metal film stack is non-conformal in at least one of thickness and phase.

Some embodiments of the present disclosure relate to a semiconductor device, comprising: a first source/drain region; a second source/drain region; a fin structure disposed between the first source/drain region and the second source/drain region, wherein the fin structure has a first sidewall, a second sidewall opposing the first sidewall, and a top surface connecting the first sidewall and the second sidewall; and a gate structure disposed over the top surface, the first sidewall and the second sidewall of the fin structure, wherein the gate structure comprises: a gate dielectric layer; a work function metal film stack on the gate dielectric layer; and a gate fill layer on the work function metal film stack, wherein the work function metal film stack has a first thickness over the top surface of the fin structure and a second thickness of along the first and second sidewalls of the fin structure, and the first thickness is greater than the second thickness.

Some embodiments of the present disclosure relate to a method, comprising forming a fin structure; forming a sacrificial gate structure over the fin structure; etching the fin structure on both sides of the sacrificial gate structure to form source/drain recesses; forming source/drain regions in source/drain recesses; removing the sacrificial gate structure to expose two sidewalls and a top surface of the fin structure; depositing a gate dielectric layer on the top surface and two sidewalls of the fin structure; depositing a work function metal film stack over the gate dielectric layer, wherein the work function metal film stack has a first thickness over the top surface of the fin structure and a second thickness of along the two sidewalls of the fin structure, and the first thickness is greater than the second thickness; and depositing a gate fill layer over the work function metal film stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first source/drain region;
a second source/drain region;
a fin structure disposed between the first source/drain region and the second source/drain region; and
a gate structure disposed over a top surface and sidewalls of the fin structure, wherein the gate structure comprises:
a gate dielectric layer; and
a work function metal film stack, wherein the work function metal film stack is non-conformal in at least one of thickness and phase.

2. The semiconductor device of claim 1, wherein the work function metal film stack has a first thickness over the top surface of the fin structure and a second thickness along the sidewalls of the fin structure, and the first thickness is greater than the second thickness.

3. The semiconductor device of claim 2, wherein the work function metal film stack comprises:
a first work function metal layer disposed on the gate dielectric layer;
a second work function metal layer disposed on the first work function metal layer; and
a third work function metal layer disposed on the second work function metal layer, wherein at least one of the first work function metal layer, the second work function metal layer, and third work function metal layer has a greater thickness over the top surface of the fin structure than over the sidewalls of the fin structure.

4. The semiconductor device of claim 3, wherein the first work function metal layer has a greater thickness over the top surface of the fin structure than over the sidewalls of the fin structure.

5. The semiconductor device of claim 3, wherein the second work function metal layer has a greater thickness over the top surface of the fin structure than over the sidewalls of the fin structure.

6. The semiconductor device of claim 3, wherein the third work function metal layer has a greater thickness over the top surface of the fin structure than over the sidewalls of the fin structure.

7. The semiconductor device of claim 1, wherein the work function metal film stack has an amorphous portion and a polycrystalline portion.

8. The semiconductor device of claim 7, wherein the work function metal film stack comprises:
a first work function metal layer disposed on the gate dielectric layer, wherein the amorphous portion is in the first work function metal layer; and
a second work function metal layer disposed on the first work function metal layer.

9. The semiconductor device of claim 8, wherein the first work function metal layer is amorphous over the top surface and the sidewalls of the fin structure.

10. The semiconductor device of claim 8, wherein the first work function metal layer is amorphous over the top surface of the fin structure and polycrystalline over the sidewalls of the fin structure.

11. A semiconductor device, comprising:
a first source/drain region;
a second source/drain region;
a fin structure disposed between the first source/drain region and the second source/drain region, wherein the fin structure has a first sidewall, a second sidewall opposing the first sidewall, and a top surface connecting the first sidewall and the second sidewall; and
a gate structure disposed over the top surface, the first sidewall and the second sidewall of the fin structure, wherein the gate structure comprises:
a gate dielectric layer;
a work function metal film stack on the gate dielectric layer; and
a gate fill layer on the work function metal film stack,
wherein the work function metal film stack has a first thickness over the top surface of the fin structure and a second thickness of along the first and second sidewalls of the fin structure, and the first thickness is greater than the second thickness.

12. The semiconductor device of claim 11, wherein a ratio of the first thickness over the second thickness is in a range between about 1.1 and about 1.5.

13. The semiconductor device of claim 12, wherein the fin structure has a width from the first sidewall to the second sidewall, and a ratio of the second thickness over the width is in a range between about 0.5 and about 1.0.

14. The semiconductor device of claim 11, wherein the work function metal film stack comprises:
a first work function metal layer disposed on the gate dielectric layer;
a second work function metal layer disposed on the first work function metal layer; and
a third work function metal layer disposed on the second work function metal layer, wherein at least one of the first work function metal layer, the second work function metal layer, and third work function metal layer has a greater thickness over the top surface of the fin structure than over the first sidewall and the second sidewall of the fin structure.

15. The semiconductor device of claim 11, wherein the work function metal film stack comprises:
an amorphous portion disposed over the top surface of the fin structure; and
a polycrystalline portion disposed on the first sidewall, the second sidewall, and the top surface of the fin structure.

16. A method, comprising:
forming a fin structure;
forming a sacrificial gate structure over the fin structure;
etching the fin structure on both sides of the sacrificial gate structure to form source/drain recesses;
forming source/drain regions in source/drain recesses;
removing the sacrificial gate structure to expose two sidewalls and a top surface of the fin structure;
depositing a gate dielectric layer on the top surface and two sidewalls of the fin structure;
depositing a work function metal film stack over the gate dielectric layer, wherein the work function metal film stack has a first thickness over the top surface of the fin structure and a second thickness of along the two sidewalls of the fin structure, and the first thickness is greater than the second thickness; and
depositing a gate fill layer over the work function metal film stack.

17. The method of claim 16, wherein depositing the work function metal film stack comprises:
forming a first work function metal layer on the gate dielectric layer;
forming a second work function metal layer on the first work function metal layer; and
forming a third work function metal layer on the second work function metal layer, wherein at least one of the first work function metal layer, the second work function metal layer, and third work function metal layer has a greater thickness over the top surface of the fin structure than over the sidewalls of the fin structure.

18. The method of claim 17, wherein depositing the work function metal film stack comprising forming one of the first, second, and third work function metal layers using an atomic layer deposition process with a reduced pressure and a reduced pulse to obtain a greater thickness on the top surface of the fin structure.

19. The method of claim 16, wherein depositing the work function metal film stack comprises:
forming an amorphous portion over the gate dielectric layer.

20. The method of claim 19, wherein depositing the work function metal film stack further comprises:
depositing a polycrystalline film on the gate dielectric layer, wherein the amorphous portion is formed on the polycrystalline film above the top surface of the fin structure.
